(19) United States
(12) Patent Application Publication
(10) Pub. No.: US 2020/0411428 A1
(43) Pub. Date: Dec. 31, 2020

(54) MEMORY DEVICES WITH A LOGIC REGION BETWEEN MEMORY REGIONS

(71) Applicant: Intel Corporation, Santa Clara, CA (US)

(72) Inventors: Aaron D. Lilak, Beaverton, OR (US); Anh Phan, Beaverton, OR (US); Gilbert W. Dewey, Beaverton, OR (US); Willy Rachmady, Beaverton, OR (US); Prashant Majhi, San Jose, CA (US); Hui Jae Yoo, Hillsboro, OR (US); Cheng-Ying Huang, Portland, OR (US); Ehren Mannebach, Tigard, OR (US)

(73) Assignee: Intel Corporation, Santa Clara, CA (US)

(21) Appl. No.: 16/454,279

(22) Filed: Jun. 27, 2019

(51) Int. Cl. H01L 23/522; H01L 25/065; H01L 25/00

(52) U.S. Cl. CPC H01L 23/5226; H01L 27/115; H01L 25/50; H01L 25/0657

(57) ABSTRACT

Disclosed herein are memory devices with a logic region between memory regions. For example, in some embodiments, a memory device may include: a first memory region; a second memory region; a logic region between the first memory region and the second memory region; and a metallization stack, wherein the first memory region is between the logic region and the metallization stack.

### BACKGROUND

Memory components typically include storage elements and circuitry to read to and write from the storage elements. The storage elements may be arranged in an array having rows and columns that can be selectively addressed.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is side, cross-sectional view of a memory device with a logic region between memory regions, in accordance with various embodiments.

FIG. 2 is a side, cross-sectional view of an example embodiment of the memory device of FIG. 1.

FIGS. 3A-3L illustrate stages in an example process of manufacturing the memory device of FIG. 2, in accordance with various embodiments.

FIG. 4 is a side, cross-sectional view of an example embodiment of the memory device of FIG. 1.

FIGS. 5A-5B illustrate stages in an example process of manufacturing the memory device of FIG. 4, in accordance with various embodiments.

FIG. 6 depicts the misalignment that may occur between interconnect subregions in a memory device, in accordance with various embodiments.

FIG. 7 depicts a catch cup structure that may be used in a memory device, in accordance with various embodiments.

FIG. 8 is a schematic illustration of a memory device including a memory array, in accordance with various embodiments.

FIG. 9 is a top view of a wafer and dies that may include a memory device, in accordance with various embodiments.

FIG. 10 is a side, cross-sectional view of an integrated circuit (IC) package that may include a memory device, in accordance with various embodiments.

FIG. 11 is a side, cross-sectional view of an IC device assembly that may include a memory device, in accordance with various embodiments.

FIG. 12 is a block diagram of an example electrical device that may include a memory device, in accordance with various embodiments.

### DETAILED DESCRIPTION

Disclosed herein are memory devices with a logic region vertically between memory regions. For example, in some embodiments, a memory device may include: a first memory region; a second memory region; a logic region between the first memory region and the second memory region; and a metallization stack, wherein the first memory region is between the logic region and the metallization stack.

The memory devices disclosed herein may include a logic region vertically “sandwiched” between two memory device arrays. The logic region may include control circuitry (e.g., including complementary metal oxide semiconductor (CMOS) transistors) that may serve to control the flow of data to and/or from the memory device arrays (which may be, for example, NAND arrays). Sharing a single logic region between an “upper” and a “lower” memory device array may increase the memory density relative to conventional memory devices (e.g., memory devices in which the control circuitry is arranged laterally relative to a memory array), and may reduce the cost per bit.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

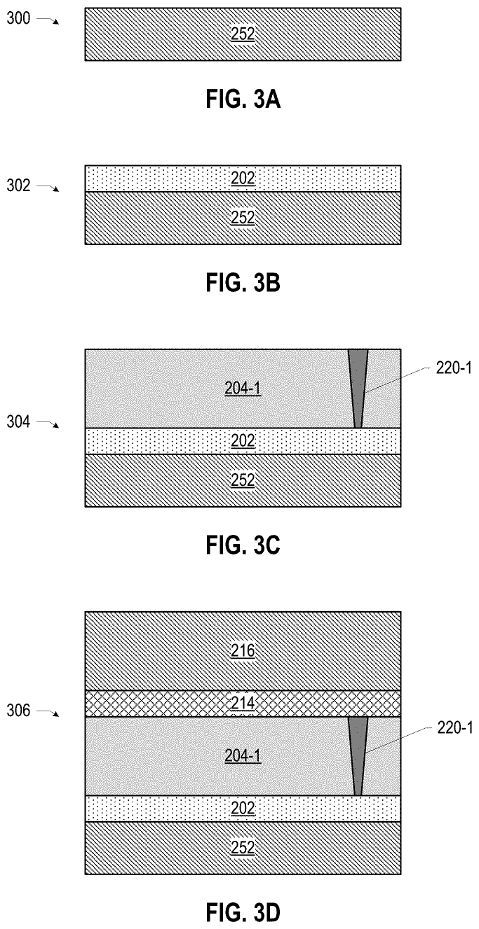

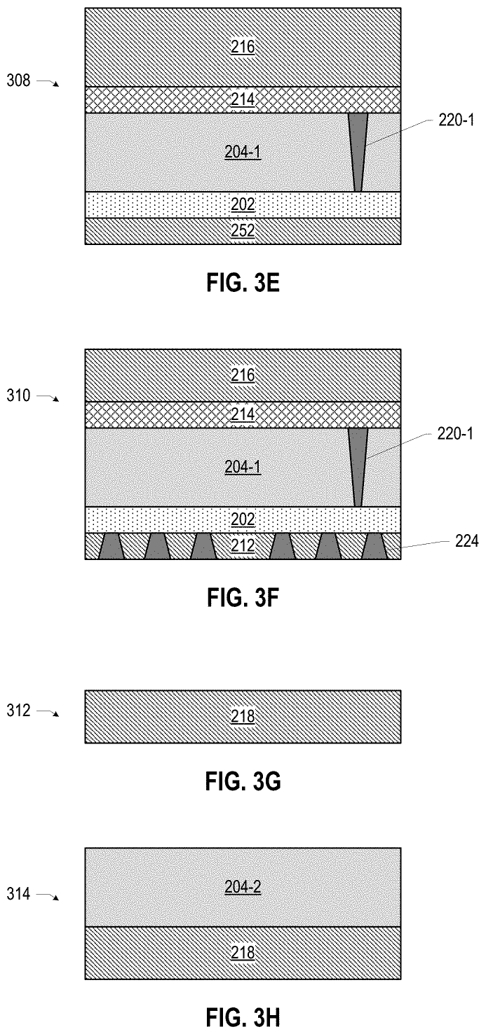

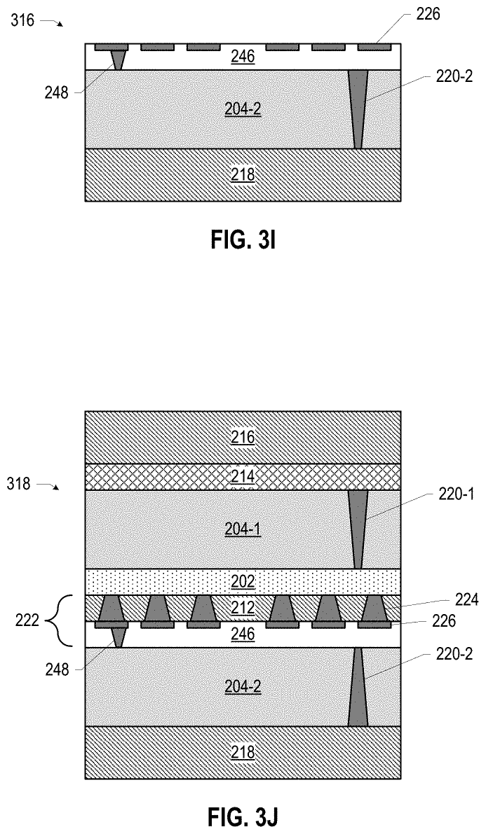

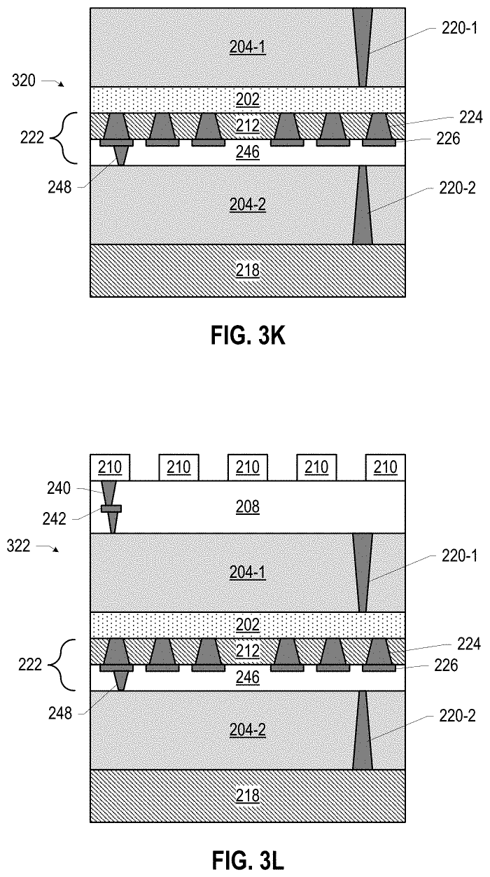

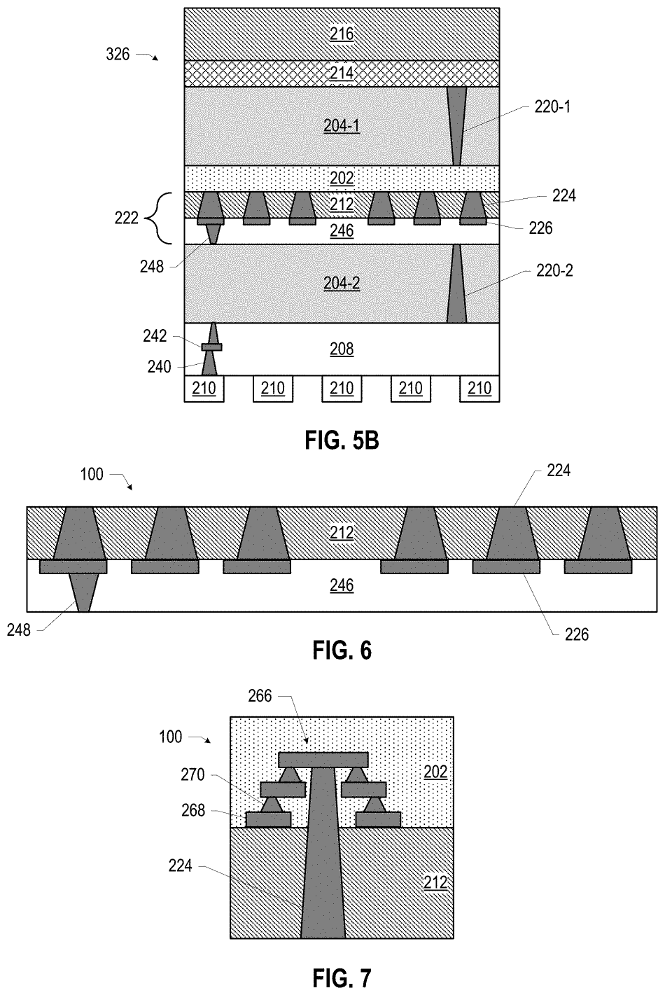

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y. For convenience, the phrase “FIG. 3” may be used to refer to the collection of drawings of FIGS. 3A-3L, and the phrase “FIG. 5” may be used to refer to the collection of drawings of FIGS. 5A-5B.

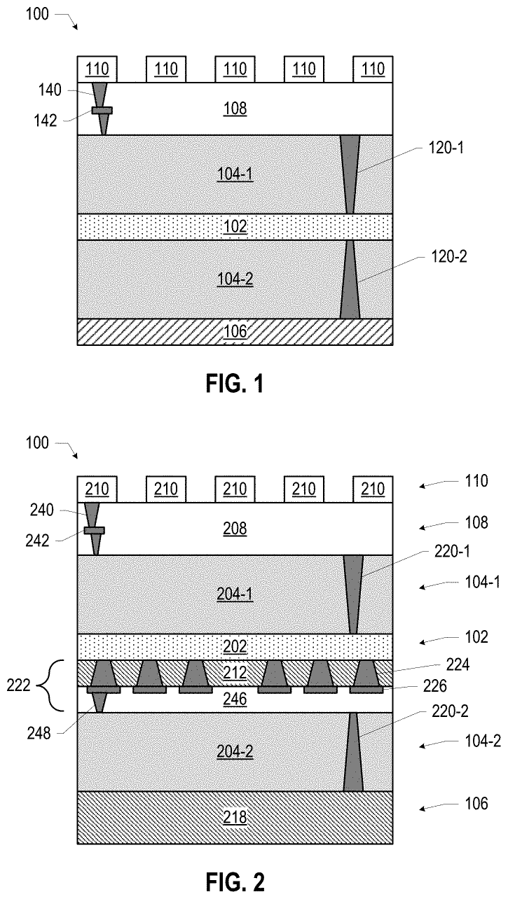

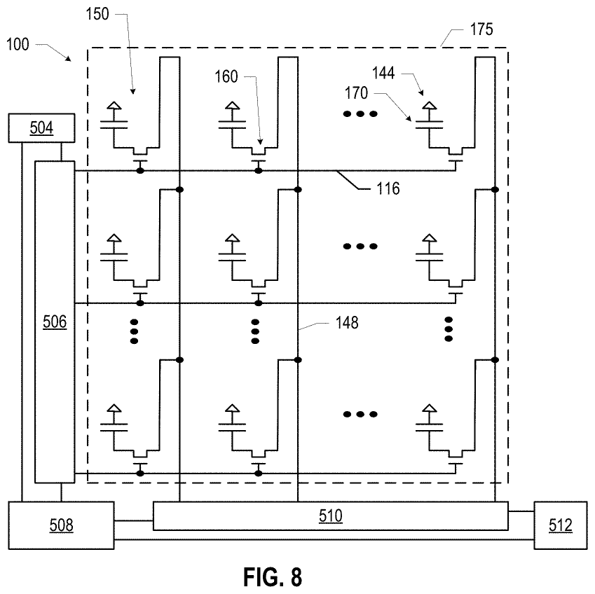

FIG. 1 is a side, cross-sectional view of a memory device 100 having a logic region 102 between two memory regions 104-1 and 104-2. The logic region 102 may include circuitry to control operation of the memory regions 104 (e.g., as discussed further below with reference to FIG. 8). The memory regions 104 may each include arrays of storage elements that can be addressed and controlled by the circuitry in the logic region 102 (e.g., during read/write operations).

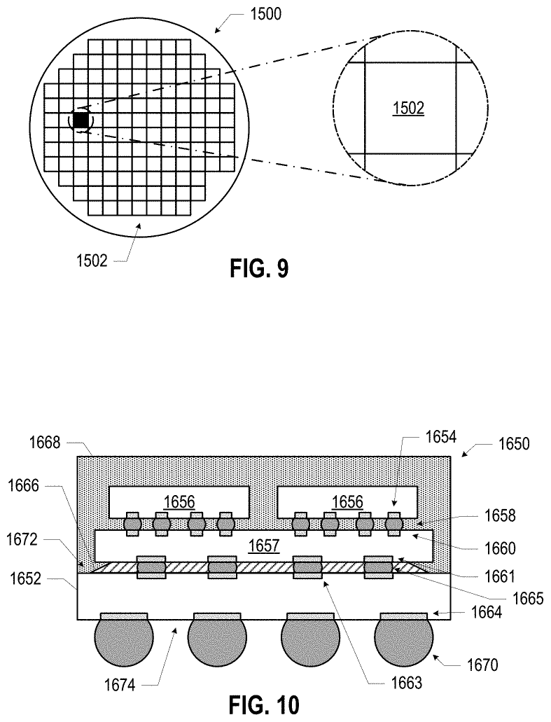

The logic region 102 may be fabricated on (and thus may include portions of) a semiconductor substrate composed of semiconductor material systems including, for example, n-type or p-type materials systems (or a combination of both). The substrate may include, for example, a crystalline substrate including a bulk silicon or a silicon-on-insulator (SOI) substructure. In some embodiments, the substrate may include alternative materials, which may or may not be combined with silicon, that include but are not limited to germanium, indium antimonide, lead telluride, indium arsenide, indium phosphide, gallium arsenide, or gallium antimonide. In other embodiments, the substrate may include amorphous oxide semiconductor materials such as indium-gallium-zinc-oxide (IGZO), organic semiconductors, or two-dimensional semiconductors such as graphene or black phosphorus. Further materials classified as group II-VI, III-V, or IV may also be used in the substrate. Although a few examples of materials for the substrate are described here, any material that may serve as a foundation for the logic region 102 of the memory device 100 may be used. The substrate may be part of a singulated die (e.g., the dies 1502 of FIG. 9) or a wafer (e.g., the wafer 1500 of FIG. 9).

The logic region 102 may include one or more transistors (e.g., CMOS transistors) formed on the substrate. A layer of transistors in the logic region 102 may be arranged laterally (e.g., left-right in the drawing of FIG. 1) relative to each other. The logic region 102 may include, for example, one or more source and/or drain (S/D) regions, gates to control current flow in the transistors between the S/D regions, and S/D contacts to route electrical signals to/from the S/D regions. The transistors may include additional features, such as device isolation regions, gate contacts, and the like. The transistors may include a wide variety of types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor may include a gate formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions may be formed within the substrate adjacent to the gate of each transistor. The S/D regions may be formed using an implantation/diffusion process or an etching/deposition process, for example. In the former process, dopants such as boron, aluminum, antimony, phosphorous, or arsenic may be ion-implanted into the substrate to form the S/D regions. An annealing process that activates the dopants and causes them to diffuse farther into the substrate may follow the ion-implantation process. In the latter process, the substrate may first be etched to form recesses at the locations of the S/D regions. An epitaxial deposition process may then be carried out to fill the recesses with material that is used to fabricate the S/D regions. In some implementations, the S/D regions may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions may be formed using one or more alternate semiconductor materials such as germanium or a group III-V material or alloy. In further embodiments, one or more layers of metal and/or metal alloys may be used to form the S/D regions. In some embodiments, the logic region 102 may include a single layer of transistors, while in other embodiments, the logic region 102 may include multiple stacked layers of transistors.

The memory regions 104 of a memory device 100 may include any suitable memory array architectures. In some embodiments, the memory region 104-1 and/or the memory region 104-2 may include a NAND device array. In some embodiments, the memory region 104-1 and/or the memory region 104-2 may include a dynamic random access memory (DRAM) device array. In some embodiments, the memory region 104-1 and/or the memory region 104-2 may include a static random access memory (SRAM) device array. In some embodiments, the memory region 104-1 and/or the memory region 104-2 may include a resistive random access memory (RRAM) device array. In some embodiments, the memory region 104-1 and the memory region 104-2 may include a same memory architecture, while in other embodiments, the memory region 104-1 may include a first memory architecture while the memory region 104-2 includes a second, different memory architecture. Further, the pitch, number of layers, orientation (e.g., whether the word line is vertical or horizontal), and other features of the memory element arrays in the memory regions 104-1 and 104-2 may differ, or may be the same. In some embodiments, the memory region 104-1 and/or the memory region 104-2 may include a cross-point memory array in which the word lines are parallel to each other and are arranged perpendicularly to the bit lines (which themselves may be parallel to each other), but any other suitable arrangement may be used. The word lines and/or the bit lines in a memory region 104 may be formed of any suitable conductive material, such as a metal (e.g., tungsten, copper, titanium, or aluminum), and the word lines and/or bit lines of a memory region 104 may be in conductive contact with electrical elements of the logic region 102 (e.g., as discussed below with reference to FIG. 8).

In some embodiments, the memory regions 104 may include one or more trenches 120 that span multiple decks of an array of memory elements. These trenches 120 may have a tapered shape, as illustrated in FIG. 1. In particular, the trenches 120 may be wider farther from the logic region 102 and narrower closer to the logic region 102. In some embodiments, a single trench 120 may span up to 32 decks of memory elements in a stacked array.

The memory device 100 may further include a metallization stack 108 such that the memory region 104-1 is between the metallization stack 108 and the logic region 102. The metallization stack 108 may provide conductive pathways between conductive contacts 110 at a face of the memory device 100 and any of the regions of the memory device 100 (e.g., the memory regions 104 and/or the logic region 102). In particular, electrical signals, such as power and/or input/output (I/O) signals, may be routed to and/or from the memory regions 104 and the logic region 102 through interconnect structures in one or more interconnect layers of the metallization stack 108. In some embodiments, the interconnect structures may include lines 142 (which may include pads on which vias land) and/or vias 140 filled with an electrically conductive material such as a metal. The lines 142 may be arranged to route electrical signals in a direction of a plane that is substantially parallel with a plane of the logic region 102 (e.g., a surface of the substrate upon which the logic region 102 is formed). For example, the lines 142 may route electrical signals in a direction in and out of the page from the perspective of FIG. 1. The vias 140 may be arranged to route electrical signals in a direction of a plane that is substantially perpendicular to the plane of the logic region 102; in other words, the vias 140 may be arranged to route electrical signals in a direction parallel to an axis of the memory region 104-1/logic region 102/memory region 104-2 stack. In some embodiments, the vias 140 may electrically couple lines 142 of different interconnect layers together.

The interconnect layers of the metallization stack 108 may include a dielectric material (e.g., an interlayer dielectric) disposed between the interconnect structures. The interconnect structures may be arranged within the interconnect layers of the metallization stack 108 to route electrical signals according to a wide variety of designs (in particular, the arrangement is not limited to the example interconnect structures depicted in FIG. 1). In some embodiments, the interconnect layers that are “higher up” in the metallization stack 108 (i.e., closer to the conductive contacts 110) may be thicker. As illustrated in FIG. 1, in some embodiments, the vias 140 in a metallization stack 108 may have a tapered shape, with the vias 140 wider closer to the conductive contacts 110 and narrower closer to the memory region 104-1. The memory device 100 may include a solder resist material (e.g., polyimide or similar material, not shown) around the conductive contacts 110. In FIG. 1 (and others of the accompanying figures), the conductive contacts 110 are illustrated as taking the form of bond pads. As noted above, the conductive contacts 110 may be electrically coupled with the vias 140/lines 142 of the metallization stack 108 and may be configured to route the electrical signals of the memory regions 104/logic region 102 to other external devices. For example, solder bonds may be formed on the one or more conductive contacts 110 to mechanically and/or electrically couple a die including the memory device 100 with another component (e.g., a package substrate, an interposer, or another die).

A support region 106 may be disposed at an opposite face of the memory device 100 relative to the conductive contacts 110. In some embodiments, the support region 106 may include a substantially solid portion of semiconductor material or insulating material (or combinations thereof), while in other embodiments, the support region 106 may be another metallization stack like the metallization stack 108, and additional conductive contacts 110 (not shown) may be disposed at the face of the support region 106; in such latter embodiments, the memory device 100 may be a “double-sided” memory device 100, having conductive contacts 110 at opposing faces.

FIG. 2 is a side, cross-sectional view of an example embodiment of the memory device 100 of FIG. 1. The memory device 100 of FIG. 2 includes conductive contacts 210 (which may serve as the conductive contacts 110 of the memory device 100 of FIG. 1, and may take the form of any suitable embodiment of the conductive contacts 110), a metallization stack 208 (which may serve as the metallization stack 108 of the memory device 100 of FIG. 1, and may take the form of any suitable embodiment of the metallization stack 108), a memory region 204-1 (which may serve as the memory region 104-1 of the memory device 100 of FIG. 1, and may take the form of any suitable embodiment of the memory region 104-1), a logic region 202 (which may serve as the logic region 102 of the memory device 100 of FIG. 1, and may take the form of any suitable embodiment of the logic region 102), a memory region 204-2 (which may serve as the memory region 104-2 of the memory device 100 of FIG. 1, and may take the form of any suitable embodiment of the memory region 104-2), and a support material 218 (which may serve as the support region 106 of the memory device 100 of FIG. 1, and may take the form of any suitable embodiment of the support region 106). As depicted, the metallization stack 208 may include one or more vias 240 and one or more lines 242, which may serve as the vias 140 and lines 142, respectively, of the memory device 100 of FIG. 1, and may take the form of any suitable embodiments of the vias 140 and lines 142, respectively. In particular, the vias 240 of the memory device 100 of FIG. 2 may have a tapered shape that is wider closer to the conductive contacts 210 and narrower closer to the logic region 202. Similarly, the memory regions 204 may include trenches 220 that may serve as the trenches 120 of the memory device 100 of FIG. 1; the trenches 220 may also have a tapered shape, and may be wider farther away from the logic region 202 and narrower closer to the logic region 202.

As noted above with reference to FIG. 1, the memory device 100 of FIG. 2 includes a logic region 202 between the memory regions 204. The logic region 202 may include interconnect structures that couple the transistors of the logic region 202 with the elements of the memory region 204-1 (e.g., word lines and bit lines). The memory device 100 of FIG. 2 also includes an interconnect region 222 between the logic region 202 and the memory region 204-2, providing electrical pathways between elements of the logic region 202 (e.g., transistors) and elements of the memory region 204-2 (e.g., word and/or bit lines). The interconnect region 222 itself includes an interconnect subregion 212 and an interconnect subregion 246 such that the interconnect subregion 212 is between the logic region 202 and the interconnect subregion 246. The interconnect subregion 212 may include vias 224 through a semiconductor or other material; this semiconductor or other material may take any of the forms of the substrate for the logic region 202 discussed above with reference to FIG. 1. In some embodiments, the vias 224 may be through-silicon vias (TSVs). The interconnect subregion 212 may have any suitable thickness; in some embodiments, the interconnect subregion 212 may have a thickness between 1 micron and 10 microns. The interconnect subregion 246 may include conductive pads 226 on which the vias 224 of the interconnect subregion 212 may land, and may also include vias 248 (and potentially other interconnect structures, not shown) to electrically connect the conductive pads 226 to the memory region 204-2. The interconnect subregion 246 may itself take the form of any of the metallization stacks discussed herein (e.g., the metallization stack 108). As depicted in FIG. 2, the vias 224 of the interconnect subregion 212 may have a tapered shape, widening towards the memory region 204-2 and narrowing towards the logic region 202. The vias 224 may be significantly larger than any vias included in the logic region 202 in any of the embodiments disclosed herein; for example, the vias 224 may have a diameter between 500 nanometers and 5 microns (or larger), while metal routing formed as part of the logic region 202 may have a diameter between 10 nanometers and 30 nanometers. The vias 248 of the interconnect subregion 246 may also have a tapered shape, widening towards the logic region 102 and narrowing towards the memory region 204-2.

FIGS. 3A-3L are side, cross-sectional views of stages in an example process of manufacturing the memory device 100 of FIG. 2, in accordance with various embodiments. Although the operations of this process are illustrated with reference to particular embodiments of the memory devices 100 disclosed herein, the process may be used to form any suitable memory devices 100. Operations are illustrated once each and in a particular order in FIG. 3, but the operations may be reordered and/or repeated as desired (e.g., with different operations performed in parallel when manufacturing multiple electronic components simultaneously).

FIG. 3A illustrates an assembly 300 including a substrate 252. The substrate 252 may take the form of any of the substrates discussed above with reference to the memory device 100 of FIG. 1. In particular, the substrate 252 may include any suitable material on which the logic region 202 may be fabricated. In some embodiments, the substrate 252 may include a semiconductor material, an insulating material, or combination of semiconductor and insulating materials. In some embodiments, the substrate 252 may be a semiconductor wafer having a thickness between 700 microns and 900 microns.

FIG. 3B illustrates an assembly 302 subsequent to forming the logic region 202 on the substrate 252 of the assembly 300 (FIG. 3A). The logic region 202 may be formed using any suitable techniques for forming a transistor device layer in an integrated circuit, and may include any of the transistor types and arrangements discussed above with reference to the logic region 102. As noted above, interconnect structures for electrically coupling transistors of the logic region 202 with elements of the memory region 204-1 (discussed below) may be included in the logic region 202.

FIG. 3C illustrates an assembly 304 subsequent to forming the memory region 204-1 on the logic region 202 of the assembly 302 (FIG. 3B). The memory region 204-1 may include any suitable stacked memory architecture, as discussed above, and may be formed using any suitable techniques. The assembly 304 may include electrical pathways between suitable elements of the memory region 204-1 and suitable elements of the logic region 202, as discussed above. As discussed above, trenches 220-1 formed in the memory region 204-1 may be formed from the exposed surface of the memory region 204-1, and may narrow towards the logic region 202, as shown.

FIG. 3D illustrates an assembly 306 subsequent to attaching a support material 216 to the exposed surface of the memory region 204-1 of the assembly 304 (FIG. 3C) with a bonding material 214. In some embodiments, the support material 216 may be a semiconductor wafer, a portion of glass, or any other suitable material. In some embodiments, the bonding material 214 may be any material suitable for securing the support material 216 to the assembly 304; in some embodiments, for example, the bonding material 214 may be an oxide material.

FIG. 3E illustrates an assembly 308 subsequent to thinning the substrate 252 of the assembly 306 (FIG. 3D). In some embodiments, the substrate 252 may be thinned using a chemical mechanical polishing (CMP) technique. The substrate 252 may be thinned to any suitable thickness; in some embodiments, the substrate 252 may be thinned to a thickness between 1 micron and 10 microns.

FIG. 3F illustrates an assembly 310 subsequent to forming vias 224 in the thinned substrate 252 of the assembly 308 (FIG. 3E), resulting in the interconnect subregion 212. The vias 224 may be formed from the exposed surface of the thinned substrate 252 (e.g., using any suitable lithographic patterning and filling technique), and may narrow towards the logic region 202. As noted above, the vias 224 may make electrical contact with elements (e.g., transistors) of the logic region 202.

FIG. 3G illustrates an assembly 312 including a support material 218. The support material 218 may take the form of any of the substrates discussed above with reference to the memory device 100 of FIG. 1. In particular, the support material 218 may include any suitable material on which the memory region 204-1 may be fabricated. In some embodiments, the support material 218 may include a semiconductor material, an insulating material, or combination of semiconductor and insulating materials. In some embodiments, the support material 218 may be a semiconductor wafer having a thickness between 700 microns and 900 microns.

FIG. 3H illustrates an assembly 314 subsequent to forming the memory region 204-2 on the support material 218 of the assembly 312 (FIG. 3G). The memory region 204-2 may include any suitable stacked memory architecture, as discussed above, and may be formed using any suitable techniques. As discussed above, trenches 220-2 formed in the memory region 204-2 may be formed from the exposed surface of the memory region 204-2, and may narrow towards the support material 218, as shown.

FIG. 3I illustrates an assembly 316 subsequent to forming the interconnect subregion 246 on the memory region 204-2 of the assembly 314 (FIG. 3H). The interconnect subregion 246 may be formed using any suitable techniques for forming a metallization stack, and may include vias 248 and conductive pads 226 that are part of electrical pathways to elements (e.g., word and/or bit lines) of the memory region 204-2. The vias 248 included in the interconnect subregion 246 may narrow towards the memory region 204-2, as shown.

FIG. 3J illustrates an assembly 318 subsequent to attaching the assembly 310 (FIG. 3F) to the assembly 316 (FIG. 3I) so that the interconnect subregion 212 of the assembly 310 is brought into contact with the interconnect subregion 246 of the assembly 316, forming the interconnect region 222. In particular, the vias 224 of the interconnect subregion 212 may make contact with corresponding conductive pads 226 of the interconnect subregion 246, completing electrical pathways between the logic region 202 and the memory region 204-2. The assembly 310 may be attached to the assembly 316 using any suitable pattern-to-pattern bonding operation, such as copper-to-copper bonding.

FIG. 3K illustrates an assembly 320 subsequent to removing the support material 216 and the bonding material 214 from the assembly 318 (FIG. 3J). In some embodiments, the support material 216 and the bonding material 214 may be removed using a CMP technique, exposing the memory region 204-1.

FIG. 3L illustrates an assembly 322 subsequent to forming the metallization stack 208 and the conductive contacts 210 on the memory region 204-1 of the assembly 320 (FIG. 3K). The metallization stack 208 (which may include vias 240 and lines 242) may be formed using any suitable technique (e.g., additive, subtractive, dual Damascene, or other techniques), as may be the conductive contacts 210. The resulting assembly 322 takes the form of the memory device 100 of FIG. 2.

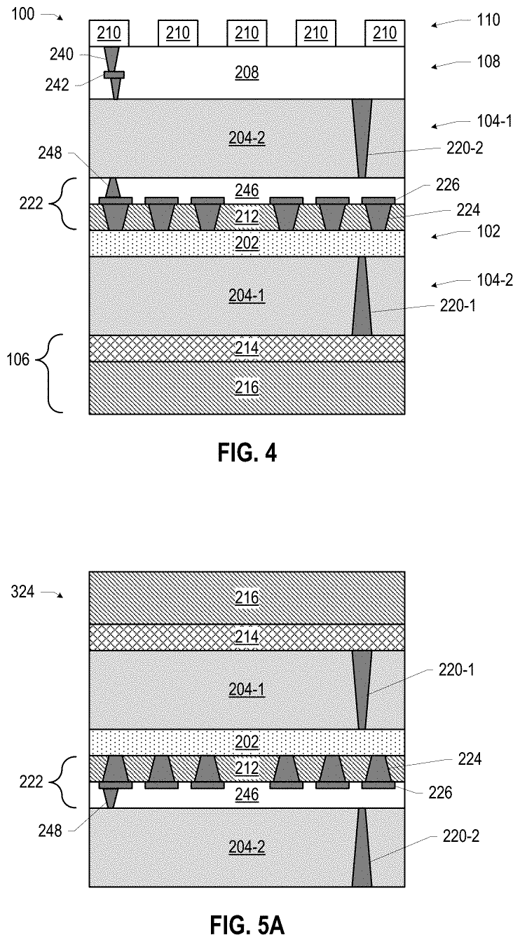

FIG. 4 is a side, cross-sectional view of another example embodiment of the memory device 100 of FIG. 1. The memory device 100 of FIG. 4 includes conductive contacts 210 (which may serve as the conductive contacts 110 of the memory device 100 of FIG. 1, and may take the form of any suitable embodiment of the conductive contacts 110), a metallization stack 208 (which may serve as the metallization stack 108 of the memory device 100 of FIG. 1, and may take the form of any suitable embodiment of the metallization stack 108), a memory region 204-2 (which may serve as the memory region 104-1 of the memory device 100 of FIG. 1, and may take the form of any suitable embodiment of the memory region 104-1), a logic region 202 (which may serve as the logic region 102 of the memory device 100 of FIG. 1, and may take the form of any suitable embodiment of the logic region 102), and a memory region 204-1 (which may serve as the memory region 104-2 of the memory device 100 of FIG. 1, and may take the form of any suitable embodiment of the memory region 104-2). The memory device 100 of FIG. 4 further includes a bonding material 214 and a support material 216, which together may serve as the support region 106 of the memory device 100 of FIG. 1. As depicted, the metallization stack 208 may include one or more vias 240 and one or more lines 242, which may serve as the vias 140 and lines 142, respectively, of the memory device 100 of FIG. 1, and may take the form of any suitable embodiments of the vias 140 and lines 142, respectively. In particular, the vias 240 of the memory device 100 of FIG. 4 may have a tapered shape that is wider closer to the conductive contacts 210 and narrower closer to the logic region 202. Similarly, the memory regions 204 may include trenches 220 that may serve as the trenches 120 of the memory device 100 of FIG. 1; the trenches 220 may also have a tapered shape, and may be wider farther away from the logic region 202 and narrower closer to the logic region 202.

As noted above with reference to FIG. 1, the memory device 100 of FIG. 4 includes a logic region 202 between the memory regions 204. The logic region 202 may include interconnect structures that couple the transistors of the logic region 202 with the elements of the memory region 204-1 (e.g., word lines and bit lines). The memory device 100 of FIG. 4 also includes an interconnect region 222 between the logic region 202 and the memory region 204-2, providing electrical pathways between elements of the logic region 202 (e.g., transistors) and elements of the memory region 204-2 (e.g., word and/or bit lines). As discussed above with reference to FIG. 2, the interconnect region 222 of FIG. 4 itself includes an interconnect subregion 212 and an interconnect subregion 246 such that the interconnect subregion 212 is between the logic region 202 and the interconnect subregion 246. The interconnect subregion 212 may include vias 224 through a semiconductor or other material; this semiconductor or other material may take any of the forms of the substrate for the logic region 202 discussed above with reference to FIG. 1. In some embodiments, the vias 224 may be TSVs. The interconnect subregion 212 of FIG. 4 may have any suitable thickness; in some embodiments, the interconnect subregion 212 may have a thickness between 1 micron and 10 microns. As discussed above with reference to FIG. 2, the interconnect subregion 246 may include conductive pads 226 on which the vias 224 of the interconnect subregion 212 may land, and may also include vias 248 (and potentially other interconnect structures, not shown) to electrically connect the conductive pads 226 to the memory region 204-2. The interconnect subregion 246 may itself take the form of any of the metallization stacks discussed herein (e.g., the metallization stack 108). As depicted in FIG. 2, the vias 224 of the interconnect subregion 212 may have a tapered shape, widening towards the memory region 204-2 and narrowing towards the logic region 102. The vias 248 of the interconnect subregion 246 may also have a tapered shape, widening towards the logic region 102 and narrowing towards the memory region 204-2. In the embodiment of FIG. 4, the interconnect region 222 is between the logic region 202 and the conductive contacts 210, while in the embodiment of FIG. 2, the logic region 202 is between the interconnect region 222 and the conductive contacts 210.

FIGS. 5A-5B are side, cross-sectional views of stages in an example process of manufacturing the memory device 100 of FIG. 4, in accordance with various embodiments. This process may begin with the assembly 318 of FIG. 3J, discussed above. Although the operations of this process are illustrated with reference to particular embodiments of the memory devices 100 disclosed herein, the process may be used to form any suitable memory devices 100. Operations are illustrated once each and in a particular order in FIG. 5, but the operations may be reordered and/or repeated as desired (e.g., with different operations performed in parallel when manufacturing multiple electronic components simultaneously).

FIG. 5A illustrates an assembly 324 subsequent to removing the support material 218 from the assembly 318 (FIG. 3J), exposing the memory region 204-2. In some embodiments, the support material 218 may be removed using a CMP technique.

FIG. 5B illustrates an assembly 326 subsequent to forming the metallization stack 208 and the conductive contacts 210 on the memory region 204-2 of the assembly 324 (FIG. 5A). The metallization stack 208 (which may include vias 240 and lines 242) may be formed using any suitable technique (e.g., additive, subtractive, dual Damascene, or other techniques), as may be the conductive contacts 210. The resulting assembly 326 takes the form of the memory device 100 of FIG. 4.

As noted above, in some of the manufacturing processes disclosed herein, the interconnect subregion 212 and the interconnect subregion 246 may be brought together after separate manufacturing operations to complete electrical pathways between the logic region 202 and the memory region 204-2 (e.g., as discussed above with reference to FIG. 3J). Various ones of the accompanying figures illustrate the vias 224 of the interconnect subregion 212 as being perfectly aligned with (e.g., laterally centered on) the conductive pads 226 of the interconnect subregion 246). During practical manufacturing operations, however, an offset may be present between the vias 224 of the interconnect subregion 212 and the conductive pads 226 of the interconnect subregion 246; that is, the vias 224 may be laterally offset in a consistent manner from their associated conductive pads 226 so that the lateral centers of the vias 224 are consistently offset from the lateral centers of the conductive pads 226. FIG. 6 depicts an example of the misalignment that may occur between interconnect subregions 212 and 246 in a memory device 100; in particular, the vias 224 are not exactly laterally centered on their associated conductive pads 226. Such misalignment may be present in any of the embodiments disclosed herein that include an interconnect subregion 212 and an interconnect subregion 246.

Although various ones of the accompanying drawings illustrate a memory device 100 with two memory regions 104 having a logic region 102 therebetween, any of the memory devices 100 disclosed herein may include more than two memory regions 104 with logic regions 102 between adjacent pairs of memory regions 104 (e.g., three, four, or more memory regions 104). Such memory devices 100 may be fabricated by appropriately repeating the operations of FIG. 3 or 5 so that a memory region 104 is fabricated in conjunction with a logic region 102, and an interconnect region 222 may be fabricated to join that logic region 102 with another memory region 104. In this manner, a memory device 100 with any desired number and stacked arrangement of memory regions 104 and logic regions 102 may be formed.

The vias 224 in an interconnect subregion 212 may make electrical contact with elements in the logic region 202 of the memory device in any suitable manner. For example, FIG. 7 depicts a catch cup structure 266 that may be included in the logic region 202 of a memory device 100 to enable reliable electrical contact between a via 224 and the logic region 202. The catch cup structure 266 includes vias 268 and lines 270 alternatingly arranged as shown to form a “cup” into which a via 224 may extend (from the interconnect subregion 212 into the logic region 202). The via 224 may ideally contact a line 270 at the “bottom” of the catch cup structure 266, but if the via 224 is misaligned, the via 224 may still make contact with one or more of the vias 268 or lines 270 forming the “sides” of the catch cup structure 266, thereby still achieving adequate electrical contact. Catch cup structures like the catch cup structure 266 may be utilized in any suitable region of a memory device 100.

As noted above, the logic region 102 may include circuitry to control the operation of the memory regions 104 of a memory device 100. Further, the memory arrays in the memory regions 104 may have any desired memory architecture. FIG. 8 is a schematic illustration of a memory device 100 including a memory array 175 having memory cells 150 with capacitors 170 and transistors 160, in accordance with various embodiments. The memory cells 150, and their interconnections, may be included in a memory region 104, and a memory device 100 may include multiple arrays of such memory cells 150 (e.g., stacked in a single memory region 104, or distributed across multiple memory regions 104). The memory device 100 of FIG. 8 may be a bidirectional cross-point array in which each column is associated with a bit line 148 driven by column select circuitry 510 (which may be included in the logic region 102). Each row may be associated with a word line 116 driven by row select circuitry 506 (which may be included in the logic region 102). During operation, read/write control circuitry 508 (which may be included in the logic region 102) may receive memory access requests (e.g., from one or more processing devices or communication chips of an electrical device, such as the electrical device 1800 discussed below, and communicated to the read/write control circuitry 508 via the conductive contacts 110 of the memory device 100), and may respond by generating an appropriate control signal (e.g., read, write 0, or write 1), as known in the art. The read/write control circuitry 508 may control the row select circuitry 506 and the column select circuitry 510 to select the desired memory cell(s) 150. Voltage supplies 504 and 512 may be controlled to provide the voltage(s) necessary to bias the memory array 175 to facilitate the requested action on one or more memory cells 150. Row select circuitry 506 and column select circuitry 510 may apply appropriate voltages across the memory array 175 to access the selected memory cells 150 (e.g., by providing appropriate voltages to the memory cells 150 to allow the desired transistors 160 to conduct current). The read/write control circuitry 508 may include sense amplifier circuitry, as known in the art. Row select circuitry 506, column select circuitry 510, and read/write control circuitry 508 may be implemented using any devices and techniques known in the art. The logic region 102 may implement further types of memory control circuitry, such as address decoding, page buffers, etc.

The memory devices 100 disclosed herein may be included in any suitable electronic component. FIGS. 9-12 illustrate various examples of apparatuses that may include any of the memory devices 100 disclosed herein, or may be included in an integrated circuit (IC) package that also includes any of the memory devices 100 disclosed herein.

FIG. 9 is a top view of a wafer 1500 and dies 1502 that may include one or more memory devices 100, or may be included in an IC package including one or more memory devices 100 (e.g., as discussed below with reference to FIG. 10) in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., as discussed above with reference to FIG. 1) and/or supporting circuitry to route electrical signals to the transistors, as well as any other IC components. In some embodiments, the dies 1502 may include any of the memory devices 100 disclosed herein.

FIG. 10 is a side, cross-sectional view of an example IC package 1650 that may include one or more memory devices 100. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the vias 140 and/or lines 142 discussed above with reference to FIG. 1.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 10 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 10 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

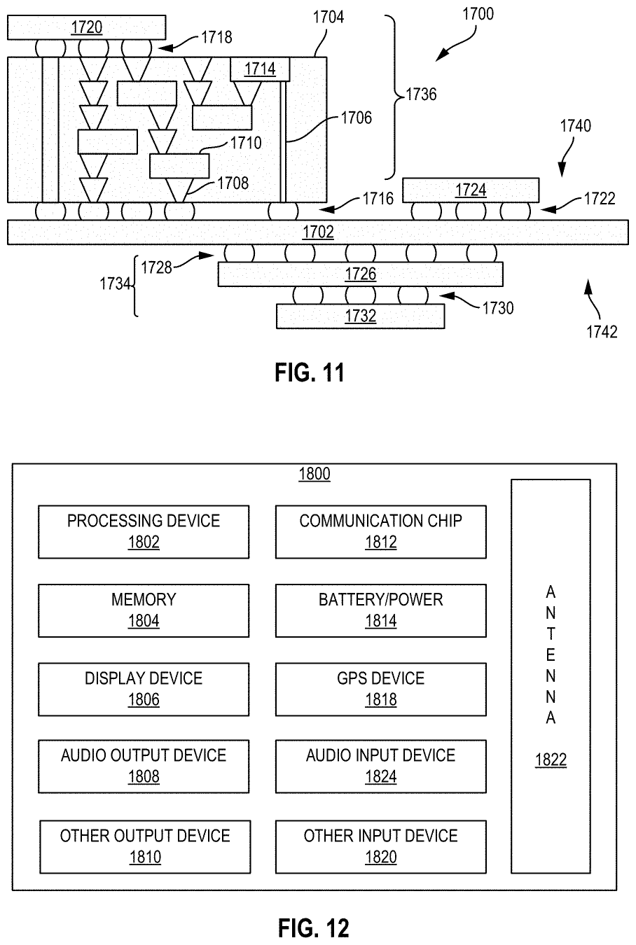

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 10 are solder balls (e.g., for a ball grid array arrangement), but any suitable second-level interconnects 16770 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 11.

The dies 1656 may take the form of any of the embodiments of the die 1502 discussed herein (e.g., may include any of the embodiments of the memory device 100). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory). In some embodiments, the die 1656 may include one or more memory devices 100.

Although the IC package 1650 illustrated in FIG. 10 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 10, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 11 is a side, cross-sectional view of an IC device assembly 1700 that may include one or more IC packages or other electronic components (e.g., a die) including one or more memory devices 100, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 10 (e.g., may include one or more memory devices 100 in a die).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 11 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 11), male and female portions of a socket, an adhesive, an underfill material, and/or any other suitable electrical and/or mechanical coupling structure.

The package-on-interposer structure 1736 may include an IC package 1720 coupled to an package interposer 1704 by coupling components 1718. The coupling components 1718 may take any suitable form for the application, such as the forms discussed above with reference to the coupling components 1716. Although a single IC package 1720 is shown in FIG. 11, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may include, for example, a die (the die 1502 of FIG. 9) including any of the memory devices 100 disclosed herein), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 11, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to TSVs 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 11 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 12 is a block diagram of an example electrical device 1800 that may include one or more memory devices 100, in accordance with any of the embodiments disclosed herein. For example, any suitable ones of the components of the electrical device 1800 may include one or more of the IC device assemblies 1700, IC packages 1650, dies 1502, or memory devices 100 disclosed herein. A number of components are illustrated in FIG. 12 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 12, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., DRAM), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is a memory device, including: a first memory region; a second memory region; a logic region between the first memory region and the second memory region; and a metallization stack, wherein the first memory region is between the logic region and the metallization stack.

Example 2 includes the subject matter of Example 1, and further specifies that the logic region includes memory control circuitry.

Example 3 includes the subject matter of any of Examples 1-2, and further specifies that the logic region includes a single layer of transistors.

Example 4 includes the subject matter of any of Examples 1-3, and further specifies that the logic region includes complementary metal oxide semiconductor (CMOS) transistors.

Example 5 includes the subject matter of any of Examples 1-4, and further specifies that the first memory region or the second memory region includes a NAND array.

Example 6 includes the subject matter of any of Examples 1-5, and further specifies that the first memory region or the second memory region includes a dynamic random access memory (DRAM) array.

Example 7 includes the subject matter of any of Examples 1-6, and further specifies that the first memory region or the second memory region includes a static random access memory (SRAM) array.

Example 8 includes the subject matter of any of Examples 1-7, and further specifies that the first memory region or the second memory region includes a resistive random access memory (RRAM) array.

Example 9 includes the subject matter of any of Examples 1-8, and further specifies that the first memory region and the second memory region have a same memory architecture.

Example 10 includes the subject matter of any of Examples 1-8, and further specifies that the first memory region and the second memory region have a different memory architecture.

Example 11 includes the subject matter of any of Examples 1-10, and further specifies that the first memory region includes a first trench, the second memory region includes a second trench, and the first trench and second trench both narrow towards the logic region.

Example 12 includes the subject matter of any of Examples 1-11, and further includes: an interconnect region between the logic region and a memory region, wherein the memory region is the first memory region or the second memory region.

Example 13 includes the subject matter of Example 12, and further specifies that the interconnect region includes through-silicon vias that narrow towards the logic region.

Example 14 includes the subject matter of Example 12, and further specifies that the interconnect region includes a first interconnect subregion and a second interconnect subregion, and the first interconnect subregion is between the second interconnect subregion and the logic region.

Example 15 includes the subject matter of Example 14, and further specifies that the first interconnect subregion includes vias that narrow towards the logic region and the second interconnect subregion includes vias that widen towards the logic region.

Example 16 includes the subject matter of any of Examples 14-15, and further specifies that the second interconnect subregion includes pads in contact with vias of the first interconnect subregion.

Example 17 includes the subject matter of Example 16, and further specifies that the pads are consistently offset from the vias.

Example 18 includes the subject matter of any of Examples 12-17, and further specifies that the interconnect region is between the logic region and the first memory region.

Example 19 includes the subject matter of any of Examples 12-17, and further specifies that the interconnect region is between the logic region and the second memory region.

Example 20 includes the subject matter of any of Examples 1-19, and further includes: conductive contacts at a face of the memory device, wherein the metallization stack is between the conductive contacts and the logic region.

Example 21 includes the subject matter of any of Examples 1-20, and further includes: a support material at a face of the memory device, wherein the second memory region is between the support material and the logic region.

Example 22 includes the subject matter of any of Examples 1-21, and further specifies that the metallization stack includes vias that narrow towards the logic region.

Example 23 is an integrated circuit (IC) package, including: a die, including a first memory region, a second memory region, a logic region between the first memory region and the second memory region, and conductive contacts, wherein the first memory region is between the logic region and the conductive contacts; and a package support, wherein the conductive contacts of the die are conductively coupled to conductive contacts of the package support.

Example 24 includes the subject matter of Example 23, and further specifies that the logic region includes memory control circuitry.

Example 25 includes the subject matter of any of Examples 23-24, and further specifies that the logic region includes a single layer of transistors.

Example 26 includes the subject matter of any of Examples 23-25, and further specifies that the logic region includes complementary metal oxide semiconductor (CMOS) transistors.

Example 27 includes the subject matter of any of Examples 23-26, and further specifies that the first memory region or the second memory region includes a NAND array.

Example 28 includes the subject matter of any of Examples 23-27, and further specifies that the first memory region or the second memory region includes a dynamic random access memory (DRAM) array.

Example 29 includes the subject matter of any of Examples 23-28, and further specifies that the first memory region or the second memory region includes a static random access memory (SRAM) array.

Example 30 includes the subject matter of any of Examples 23-29, and further specifies that the first memory region or the second memory region includes a resistive random access memory (RRAM) array.

Example 31 includes the subject matter of any of Examples 23-30, and further specifies that the first memory region and the second memory region have a same memory architecture.

Example 32 includes the subject matter of any of Examples 23-30, and further specifies that the first memory region and the second memory region have a different memory architecture.

Example 33 includes the subject matter of any of Examples 23-32, and further specifies that the first memory region includes a first trench, the second memory region includes a second trench, and the first trench and second trench both narrow towards the logic region.

Example 34 includes the subject matter of any of Examples 23-33, and further specifies that the die further includes: an interconnect region between the logic region and a memory region, wherein the memory region is the first memory region or the second memory region.

Example 35 includes the subject matter of Example 34, and further specifies that the interconnect region includes through-silicon vias that narrow towards the logic region.

Example 36 includes the subject matter of Example 34, and further specifies that the interconnect region includes a first interconnect subregion and a second interconnect subregion, and the first interconnect subregion is between the second interconnect subregion and the logic region.

Example 37 includes the subject matter of Example 36, and further specifies that the first interconnect subregion includes vias that narrow towards the logic region and the second interconnect subregion includes vias that widen towards the logic region.

Example 38 includes the subject matter of any of Examples 36-37, and further specifies that the second interconnect subregion includes pads in contact with vias of the first interconnect subregion.

Example 39 includes the subject matter of Example 38, and further specifies that the pads are consistently offset from the vias.

Example 40 includes the subject matter of any of Examples 34-39, and further specifies that the interconnect region is between the logic region and the first memory region.

Example 41 includes the subject matter of any of Examples 34-39, and further specifies that the interconnect region is between the logic region and the second memory region.

Example 42 includes the subject matter of any of Examples 23-41, and further specifies that the die further includes: a metallization stack, wherein the metallization stack is between the conductive contacts and the logic region.

Example 43 includes the subject matter of Example 42, and further specifies that the metallization stack includes vias that narrow towards the logic region.

Example 44 includes the subject matter of any of Examples 23-43, and further specifies that the die further includes: a support material at a face of the die, wherein the second memory region is between the support material and the logic region.

Example 45 includes the subject matter of any of Examples 23-44, and further specifies that the package support includes an interposer.

Example 46 includes the subject matter of any of Examples 23-44, and further specifies that the package support includes a package substrate.

Example 47 includes the subject matter of any of Examples 23-46, and further includes: an underfill material between the die and the package support.

Example 48 includes the subject matter of any of Examples 23-47, and further specifies that the IC package is a ball grid array package.

Example 49 is a computing device, including the IC package of any of Examples 23-48 and a circuit board coupled to the IC package.

Example 50 includes the subject matter of Example 49, and further specifies that the circuit board is a motherboard.

Example 51 includes the subject matter of any of Examples 49-50, and further specifies that the computing device is a wearable computing device.

Example 52 includes the subject matter of any of Examples 49-50, and further specifies that the computing device is a handheld computing device.

Example 53 includes the subject matter of any of Examples 49-50, and further specifies that the computing device is a server computing device.

Example 54 includes the subject matter of any of Examples 49-53, and further includes: a display communicatively coupled to the circuit board.

Example 55 includes the subject matter of any of Examples 49-54, and further includes: wireless communication circuitry communicatively coupled to the circuit board.

Example 56 is a method of manufacturing a memory device, including: forming a first assembly including a transistor region below a first stacked memory array; forming a second assembly including second stacked memory array; and attaching the first and second assemblies so that the transistor region is between the first stacked memory array and the second stacked memory array.

Example 57 includes the subject matter of Example 56, and further specifies that the first stacked memory array and the second stacked memory array have different memory architectures.

Example 58 includes the subject matter of any of Examples 56-57, and further specifies that the first assembly includes vias in contact with the transistor region.

Example 59 includes the subject matter of Example 58, and further specifies that the second assembly includes an interconnect region including conductive pads, and wherein the conductive pads contact the vias when the first and second assemblies are attached.

Example 60 includes the subject matter of any of Examples 58-59, and further specifies that the vias are through-silicon vias.

Example 61 includes the subject matter of any of Examples 58-59, and further specifies that the vias extend into catch cup structures in the transistor region.

Example 62 includes the subject matter of any of Examples 56-61, and further specifies that the first and second stacked memory arrays are NAND arrays.

Example 63 includes the subject matter of any of Examples 56-62, and further specifies that the transistor region includes complementary metal oxide semiconductor (CMOS) transistors.

1. A memory device, comprising:
a first memory region;
a second memory region;
a logic region between the first memory region and the second memory region; and
a metallization stack, wherein the first memory region is between the logic region and the metallization stack.

2. The memory device of claim 1, wherein the logic region includes memory control circuitry.

3. The memory device of claim 1, wherein the logic region includes a single layer of transistors.

4. The memory device of claim 1, wherein the first memory region or the second memory region includes a NAND array, a dynamic random access memory (DRAM) array, a static random access memory (SRAM) array, or a resistive random access memory (RRAM) array.

5. The memory device of claim 1, wherein the first memory region and the second memory region have a different memory architecture.

6. The memory device of claim 1, wherein the first memory region includes a first trench, the second memory region includes a second trench, and the first trench and second trench both narrow towards the logic region.

7. The memory device of claim 1, wherein the metallization stack includes vias that narrow towards the logic region.

8. An integrated circuit (IC) package, comprising:
a die, including:
a first memory region,
a second memory region,
a logic region between the first memory region and the second memory region, and
conductive contacts, wherein the first memory region is between the logic region and the conductive contacts; and
a package support, wherein the conductive contacts of the die are conductively coupled to conductive contacts of the package support.

9. The IC package of claim 8, wherein the logic region includes memory control circuitry.

10. The IC package of claim 8, wherein the die further includes:
an interconnect region between the logic region and a memory region, wherein the memory region is the first memory region or the second memory region.

11. The IC package of claim 10, wherein the interconnect region includes through-silicon vias that narrow towards the logic region.

12. The IC package of claim 10, wherein the interconnect region includes a first interconnect subregion and a second interconnect subregion, and the first interconnect subregion is between the second interconnect subregion and the logic region.

13. The IC package of claim 12, wherein the first interconnect subregion includes vias that narrow towards the logic region and the second interconnect subregion includes vias that widen towards the logic region.

14. The IC package of claim 12, wherein the second interconnect subregion includes pads in contact with vias of the first interconnect subregion.

15. The IC package of claim 14, wherein the pads are consistently offset from the vias.

16. The IC package of claim 8, wherein the package support includes a package substrate.

17. A method of manufacturing a memory device, comprising:
forming a first assembly including a transistor region below a first stacked memory array;
forming a second assembly including second stacked memory array; and
attaching the first and second assemblies so that the transistor region is between the first stacked memory array and the second stacked memory array.

18. The method of claim 17, wherein the first stacked memory array and the second stacked memory array have different memory architectures.

19. The method of claim 17, wherein the first assembly includes vias in contact with the transistor region.

20. The method of claim 19, wherein the second assembly includes an interconnect region including conductive pads, and wherein the conductive pads contact the vias when the first and second assemblies are attached.
